(19) United States
(12) Patent Application Publication
(10) Pub. No.: US 2026/0261274 A1
(43) Pub. Date: Sep. 3, 2026

(54) DIGITAL TRANSMITTER INCLUDING RADIO FREQUENCY DIGITAL TO ANALOG CONVERTER (RFDAC) OVERSAMPLE RATE DOUBLER

(71) Applicant: QUALCOMM Incorporated, San Diego, CA (US)

(72) Inventors: Mu LU, San Mateo, CA (US); Cheng-Han WANG, San Jose, CA (US)

(21) Appl. No.: 19/067,072

(22) Filed: Feb. 28, 2025

(51) Int. Cl. H04B 1/00; H04B 1/04

(52) U.S. Cl. CPC H04B 1/0003; H04B 1/04

(57) ABSTRACT

A transmitter, including: a first delay element configured to delay a first digital signal to generate a delayed second digital signal; a first delay element configured to delay a first digital signal to generate a delayed second digital signal; a first digital modulator configured to modulate a clock signal with the first digital signal to generate a first digital radio frequency (RF) signal; a second digital modulator configured to modulate the clock signal with the second digital signal to generate a second digital RF signal; a first radio frequency digital to analog converter (RFDAC) configured to convert the first digital RF signal into a first analog RF signal; a second RFDAC configured to convert the second digital RF signal to generate a second analog RF signal; and a signal combiner configured to combine the first analog RF signal with the second analog RF signal to generate an output RF signal.

### FIELD

This disclosure relates generally to radio frequency (RF) transmitters, and in particular, to a digital transmitter RF digital to analog converter (RFDAC) oversample rate doubler.

### BACKGROUND

A transmitter may include a digital to analog converter (DAC) configured to convert a digital signal to generate an analog signal for further processing for transmission. Some transmitters may convert the digital signal directly to a radio frequency (RF) signal using a radio frequency digital to analog converter (RFDAC). As a result of the process of converting the digital signal into the RF signal, DAC images may be created on either side of the fundamental frequency of the RF signal spaced apart by the sampling rate associated with converting the digital signal into the RF signal. These DAC images may cause spectrum mask requirements imposed on the transmitter output to be out of specification.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to a transmitter. The transmitter includes: a first delay element configured to delay a first digital signal to generate a second digital signal; a first delay element configured to delay a first digital signal to generate a second digital signal; a first digital modulator configured to modulate a clock signal with the first digital signal to generate a first digital radio frequency (RF) signal; a second digital modulator configured to modulate the clock signal with the second digital signal to generate a second digital RF signal; a first radio frequency digital to analog converter (RFDAC) configured to convert the first digital RF signal into a first analog RF signal; a second RFDAC configured to convert the second digital RF signal to generate a second analog RF signal; and a signal combiner configured to combine the first analog RF signal with the second analog RF signal to generate an output RF signal.

Another aspect of the disclosure relates to a method of generating an output RF signal. The method includes: modulating a clock signal with a first digital signal to generate a first digital radio frequency (RF) signal; converting the first digital RF signal into a first analog RF signal; delaying the first digital signal to generate a second digital signal; modulating the clock signal with the second digital signal to generate a second digital RF signal; converting the second digital RF signal into a second analog RF signal; and combining the first analog RF signal with the second analog RF signal to generate the output RF signal.

Another aspect of the disclosure relates to a transmitter. The transmitter includes: means for modulating a clock signal with a first digital signal to generate a first analog digital radio frequency (RF) signal; means for converting the first digital signal into a first analog RF signal; means for delaying the first digital signal to generate a second digital signal; means for modulating the clock signal with the second digital signal to generate a second digital RF signal; means for converting the second digital RF signal into a second analog RF signal; and means for combining the first analog RF signal with the second analog RF signal to generate an output RF signal.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1A illustrates a block diagram of an example transmitter in accordance with an aspect of the disclosure.

FIG. 1B illustrates a signal diagram of an example radio frequency (RF) signal IOUT of the transmitter of FIG. 1A in accordance with another aspect of the disclosure.

FIG. 1C illustrates a frequency spectrum diagram of an example normalized power of an RF signal IOUT of the transmitter of FIG. 1A in accordance with another aspect of the disclosure.

FIG. 2A illustrates a block diagram of an example transmitter in accordance with another aspect of the disclosure.

FIG. 2B illustrates a signal diagram of an example RF signal IOUT of the transmitter of FIG. 2A in accordance with another aspect of the disclosure.

FIG. 2C illustrates a frequency spectrum diagram of an example normalized output signal power POUT of the transmitter of FIG. 2A in accordance with another aspect of the disclosure.

FIG. 3 illustrates a block diagram of another example transmitter in accordance with another aspect of the disclosure.

FIG. 4 illustrates a block diagram of another example transmitter in accordance with another aspect of the disclosure.

FIG. 5 illustrates a block diagram of another example transmitter in accordance with another aspect of the disclosure.

FIG. 6 illustrates a block diagram of another example transmitter in accordance with another aspect of the disclosure.

FIG. 7 illustrates a block diagram of another example transmitter in accordance with another aspect of the disclosure.

FIG. 8 illustrates a flow diagram of an example method of generating an output radio frequency (RF) signal in accordance with another aspect of the disclosure.

FIG. 9 illustrates a block diagram of an example wireless communication system in accordance with another aspect of the disclosure.

FIG. 10 illustrates a block diagram of an example transceiver in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

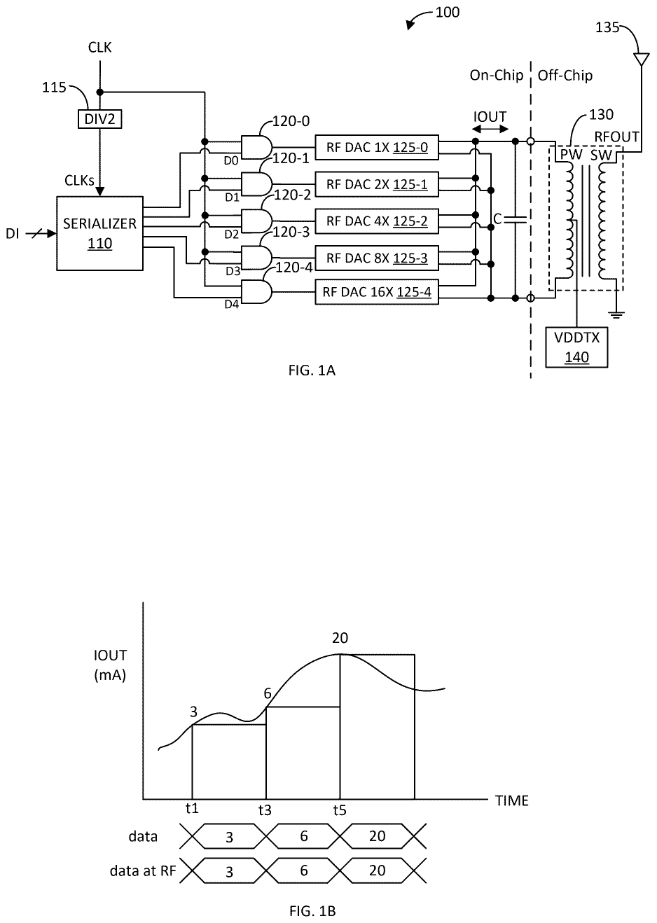

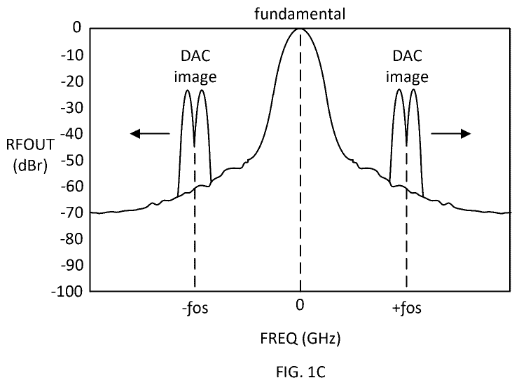

FIG. 1A illustrates a block diagram of an example transmitter 100 in accordance with an aspect of the disclosure. As an example, the transmitter 100 may be configured to generate an ultra wideband (UWB) signal for wireless communication. However, the transmitter 100 may be used in many applications including for wireless wide area network (WWAN) communications (e.g., communications compliant with New Radio (NR) 5^{th} generation (5G), and/or 6^{th} generation (6G) standards), wireless local area network (WLAN) (e.g., communications compliant with WiFi), short range wireless communications (e.g., Bluetooth), personal area network (PAN) communications, and others.

The transmitter 100 is implemented as a digital transmitter including a radio frequency (RF) digital to analog converter (DAC) or “RFDAC” for short. The transmitter 100 includes a serializer 110, a frequency divider (e.g., a divide-by-two (DIV2)) 115, a set of digital modulators (e.g., logic gates, such as AND gates) 120-0 to 120-4, a set of RFDACs 125-0 to 125-4, an output capacitor C, a balun 130 including a primary winding (PW) and a secondary winding (SW), an antenna (e.g., an antenna array) 135, and a transmitter supply voltage generator (VDDTX) 140.

The serializer 110 is configured to receive an input parallel digital signal DI and generate a serialized digital signal D0-D4 based on a sampling clock signal CLKs. The sampling clock signal CLKs may be generated by frequency dividing an oversampling clock signal CLK by substantially two (2) by frequency divider 115. As an example, the oversampling clock signal CLK may have a frequency range from 6.5 giga Hertz (GHz) to 9 GHz. In the examples provided herein, the oversampling clock signal CLK is assumed to be 8 GHz, although it may have a different frequency such as between 6.5 GHz to 9 GHz or other. Accordingly, the serializer 110 outputs two samples of the serialized digital signal D0-D4 per clock cycle of the sampling clock signal CLKs. Although the serialized digital signal D0-D4 has a bitlength of five (5) bits, it shall be understood that the serialized digital signal D0-D4 may have a different bitlength.

The set of digital modulators 120-0 to 120-4 include respective first inputs configured to receive the oversampling clock signal CLK. The set of digital modulators 120-0 to 120-4 include respective second inputs configured to receive the individual binary-weighted bits of the serialized digital signal D0-D4, respectively. The set of RFDACs 125-0 to 125-4 include inputs coupled to outputs of the set of digital modulators 120-0 to 120-4, respectively. The set of RFDACs 125-0 to 125-4 are configured to generate one or more binary-weighted output currents based on the value of the serialized digital signal D0-D4. The binary-weighted output currents (if two or more) are combined or summed together to generate an output current IOUT (RF signal). For example, the set of binary-weighted output currents generated by the set of RFDACs 125-0 to 125-4 are 1×, 2×, 4×, 8×, 16×, and 32× based on a digital value of 11111 of the digital signal, respectively.

The output current IOUT generated by the set of RFDACs 125-0 to 125-4 flows through the primary winding (PW) of the balun 130. That is, the outputs of the set of RFDACs 125-0 to 125-4 are coupled across the primary winding (PW) of the balun 130. The transmitter supply voltage generator (VDDTX) 140 is configured to generate and provide a supply voltage VDDTX to the set of RFDACs 125-0 to 125-4 via a center tap of the primary winding (PW) of the balun 130. The balun 130, the transmitter supply voltage generator (VDDTX) 140, and antenna 135 may be off-chip as indicated by the vertical large-dashed line, and the remaining components of the transmitter 100 may be on-chip.

The output capacitor C is also coupled across the primary winding (PW) of the balun 130. As discussed further herein, the capacitor C and balun 130 collectively filter the output current IOUT to remove some of the DAC images created by the digital to analog conversion. The output current IOUT flowing through the primary winding (PW) electromagnetically induces an output transmit RF signal RFOUT across the secondary winding (SW) of the balun 130. The antenna 135 is coupled to the secondary winding (SW) of the balun 130 to receive and wirelessly radiate the output RF signal RFOUT.

FIG. 1B illustrates a signal diagram of an example output signal IOUT of the transmitter 100 in accordance with another aspect of the disclosure. The horizontal axis of the signal represents time. The vertical axis represents the output signal current IOUT in milliAmps (mA) collectively generated by of the set of RFDACs 125-0 to 125-4 based on a set of values of the serialized digital signal D0-D4.

According to this example, at time t1, which coincides with a clocking edge of the oversampling clock signal CLK, the digital value of the serialized digital signal D0-D4 is three (3) (e.g., 00011). In response, the set of RFDACs 125-0 to 125-4 generates a continuous RF current IOUT with a value of three (3) mA at time t1. Then, in the next (second) clocking edge of the oversampling clock signal CLK at time t3, the digital value of the serialized digital signal D0-D4 is six (3) (e.g., 00110). In response, the set of RFDACs 125-0 to 125-4 generates a continuous RF current IOUT with a value of six (6) mA at time t3. Then, in the next (third) clocking edge of the oversampling clock signal CLK at time t5, the digital value of the serialized digital signal D0-D4 is six (3) (e.g., 10100). In response, the set of RFDACs 125-0 to 125-4 generates a continuous RF current IOUT with a value of 20 mA at time t5.

FIG. 1C illustrates a frequency spectrum diagram of an example normalized power of the output RF signal RFOUT of the transmitter 100 in accordance with another aspect of the disclosure. The horizontal axis of the frequency spectrum diagram represents frequency. The vertical axis of the frequency spectrum diagram represents the normalized power in decibel relative (dBr) associated with the output RF signal RFOUT generated by the set of RFDACs 125-0 to 125-4.

As depicted, the frequency spectrum diagram of the normalized power of the output RF signal RFOUT of the transmitter 100 includes a fundamental frequency peaking at zero (0) dBr at zero (0) Hz, and falls therefrom to about −70dBR at negative and positive frequencies beyond the DAC image frequencies at−ƒos and +ƒos, respectively. The frequency spectrum diagram of the normalized power of the output RF signal RFOUT of the transmitter 100 includes DAC images at −ƒos and +ƒos, respectively. For example, the frequency spacing between the DAC images is substantially the same as the frequency of the oversampling clock signal CLK.

The DAC images are generally undesirable as they may cause the transmitter 100 to generate out-of-band signals that violate regulatory agencies requirements for separating communication bands. As the output power requirements of the transmitter 100 is increased, the DAC images increases making it more difficult to meet spectrum mask requirements set by regulatory agencies. The output capacitor C and balun 130 are configured to filter out some of the DAC images, but since they are close in frequency to the fundamental, the filter order may not be sufficient to provide the needed DAC image rejection.

It would be desirable to move the DAC images further out in frequency from the fundamental so that the output capacitor C and the balun 130 may be able to provide sufficient DAC image rejection in order to meet spectrum mask requirements. Further, it would also be desirable to move the DAC images further out in frequency in a manner that is not too complicated and does not require significant circuit or integrated circuit (IC) area to effectuate the outward DAC image separation.

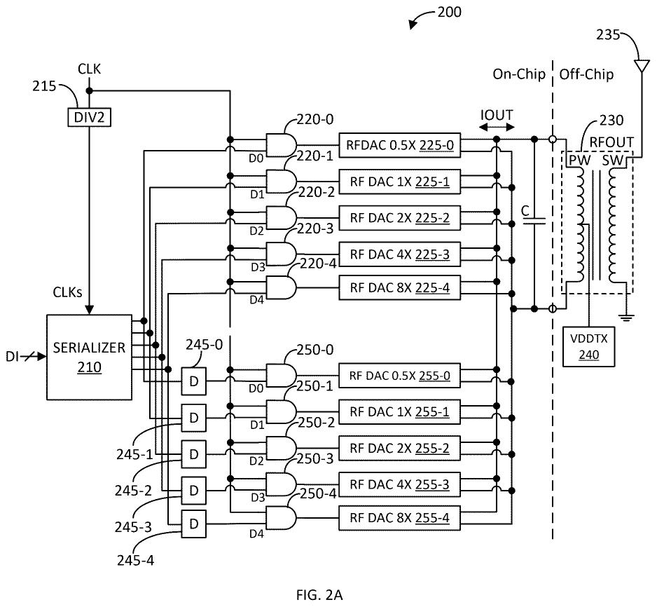

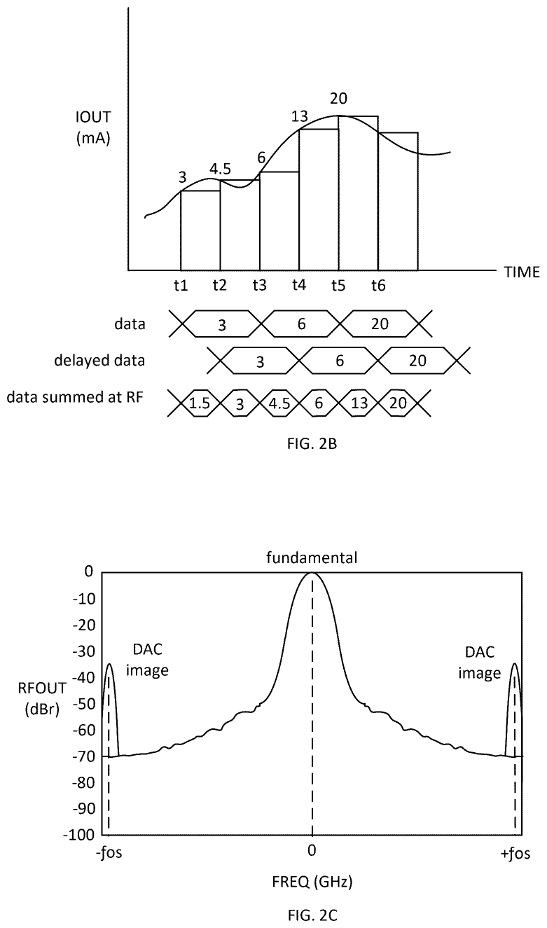

FIG. 2A illustrates a block diagram of an example transmitter 200 in accordance with another aspect of the disclosure. The transmitter 200 is similar to transmitter 100 but includes similar elements including a serializer 210, a frequency divider (e.g., a divide-by-two (DIV2)) 215, a first set of logic (e.g., AND) gates 220-0 to 220-4, a first set of RFDACs 225-0 to 225-4, an output capacitor C, a balun 230, an antenna (e.g., an antenna array) 235, and a transmitter supply voltage (VDDTX) generator 240. The arrangements of these elements are per the transmitter 100 previously discussed in detail.

The transmitter 200 further includes a set of delay elements 245-0 to 245-4, a second set of logic (e.g., AND) gates 250-0 to 250-4, and a second set of RFDACs 255-0 to 255-4. The set of delay elements 245-0 to 245-4 include inputs coupled to the serialized digital signal outputs D0 to D4 of the serializer 210, respectively. The second set of digital modulators (e.g., logic gates, such as AND gates) 250-0 to 250-4 include respective first inputs configured to receive the oversampling clock signal CLK. The second set of digital modulators 250-0 to 250-4 include respective second inputs coupled to outputs of the set of delay elements 245-0 to 245-4, respectively.

The second set of RFDACs 255-0 to 255-4 include inputs coupled to outputs of the second set of digital modulators 250-0 to 250-4, respectively. The second set of RFDACs 255-0 to 255-4 include outputs coupled across the primary winding (PW) of the balun 230, respectively. The second set of RFDACs 255-0 to 255-4 are configured to receive the transmitter supply voltage VDDTX via the center tap of the primary winding (PW) of the balun 230 from the transmitter supply voltage generator 240.

Each of the set of delay elements 245-0 to 245-4 are configured to delay each sample of the serialized digital signal D0 to D4 by substantially half a clock period of the oversampling clock signal CLK. Further, the first set of RFDACs 225-0 to 225-4 are configured to generate half of the output current IOUT of the transmitter 200. For example, the first set of RFDACs 225-0 to 225-4 are configured to generate binary-weighted currents based on the serialized digital signal D0 to D4 value of 11111 of 0.5×, 1×, 2×, 4×, 8×, and 16×, respectively.

Similarly, the second set of RFDACs 255-0 to 255-4 are configured to generate the other half of the output current IOUT as compared the set the set of RFDACs 125-0 to 125-4 of transmitter 200. For example, the second set of RFDACs 225-0 to 225-4 are configured to generate binary-weighted currents based on the delayed serialized digital signal D0 to D4 value of 11111 of 0.5×, 1×, 2×, 4×, 8×, and 16×, respectively. As each of the first and second sets of RFDACs 225-0 to 225-4/250-0 to 250-4 generates half of the output current IOUT, there may be substantially no circuit or IC area size penalty to employ the first and second sets of RFDACs 225-0 to 225-4/250-0 to 250-4 in transmitter 200.

The effect of delaying the serialized digital signal D0 to D4 by substantially half-a-clock period of the oversampling clock signal CLK is to double the oversampling of the serialized digital signal D0 to D4. This is better explained with reference to the following signal diagram.

However, it shall be understood that more than one delay element-digital modulator-RF DAC may be coupled in parallel with the digital modulator (e.g., 220-0 to 220-4) and RFDAC (e.g., 225-0 to 225-4) to achieve a higher oversampling rate (e.g., 3×, 4×, 8×, etc). As an example, three (3) additional delay elements-digital modulators-RF DACs may be coupled in parallel with digital modulator (e.g., 220-0 to 220-4) and RFDAC (e.g., 225-0 to 225-4) to achieve a 4× oversampling rate. In such case, the delay elements of the three additional delay elements-digital modulators-RF DACs may effectuate signal delays of ¼, ½, and ¾ of a clock period. Or more generally, N−1 number of delay elements-digital modulators-RF DACs may be coupled in parallel with the digital modulator (e.g., 220-0 to 220-4) and RFDAC (e.g., 225-0 to 225-4) to achieve an oversampling rate of NX, where the corresponding delay elements effectuate signal delays of 1/N to (N−1)/N, respectively.

FIG. 2B illustrates a signal diagram of an example output signal IOUT of the transmitter 200 in accordance with another aspect of the disclosure. The horizontal axis of the signal represents time. The vertical axis represents the output signal current IOUT in milliAmps (mA) collectively generated by of the first set of RFDACs 125-0 to 125-4 based on a set of values of the serialized digital signal D0-D4 and the second set of RFDACs 125-0 to 125-4 based on a set of values of the delayed serialized digital signal D0-D4.

According to this example, at time t1, which coincides with a clocking edge of the oversampling clock signal CLK, the digital value of the serialized digital signal D0-D4 is three (3) (e.g., 00011) and the digital value of the delayed digital signal D0-D4 is zero (e.g., 00000). In response, the first and second sets of RFDACs 225-0 to 225-4 and 255-0 to 255-4 collectively generate a continuous RF current IOUT with a current value of (1*0.5+1*1)+(0)=1.5 mA.

Then, in the next (second) clocking edge of the oversampling clock signal CLK at time t2, the digital value of the serialized digital signal D0-D4 is still three (3) (e.g., 00011), and the digital value of the delayed serialized digital signal D0-D4 is also three (3) (e.g., 00011). In response, the first and second sets of RFDACs 225-0 to 225-4 and 255-0 to 255-4 collectively generate a continuous RF current IOUT with a current value of 1*0.5+1*1)+(1*0.5+1*1)=1.5 mA+1.5 mA=3mA.

Then, in the next (third) clocking edge of the oversampling clock signal CLK at time t3, the digital value of the serialized digital signal D0-D4 is now six (6) (e.g., 00110), and the digital value of the delayed serialized digital signal D0-D4 is also three (3) (e.g., 00011). In response, the first and second sets of RFDACs 225-0 to 225-4 and 255-0 to 255-4 collectively generate a continuous RF current IOUT with a current value of (0*0.5+1*1+1*2)+(1*0.5+1*1)=(0+1+2)+(0.5+1)=3+1.5 =4.5 mA

Then, in the next (fourth) clocking edge of the oversampling clock signal CLK at time t4, the digital value of the serialized digital signal D0-D4 is six (6) (e.g., 00110), and the digital value of the delayed serialized digital signal D0-D4 is now six (6) (e.g., 00110). In response, the first and second sets of RFDACs 225-0 to 225-4 and 255-0 to 255-4 collectively generate a continuous RF current IOUT with a current value of (0*0.5+1*1+1*2)+(0*0.5+1*1+1*2)=(0+1+2)+(0+1+2)=3+3=6 mA.

Then, in the next (fifth) clocking edge of the oversampling clock signal CLK at time t5, the digital value of the serialized digital signal D0-D4 is now 20 (e.g., 10100), and the digital value of the delayed serialized digital signal D0-D4 is six (6) (e.g., 00110). In response, the first and second sets of RFDACs 225-0 to 225-4 and 255-0 to 255-4 collectively generate a continuous RF current IOUT with a current value of (0*0.5+1*0+1*2+0*4+1*8) mA+(0*0.5+1*1+1*2)=(0+0+2+0+8)+(0*0.5+1*1+1*2)=10+3=13 mA.

Then, in the next (fifth) clocking edge of the oversampling clock signal CLK at time t6, the digital value of the serialized digital signal D0-D4 is 20 (e.g., 10100), and the digital value of the delayed serialized digital signal D0-D4 is now (20) (e.g., 10100). In response, the first and second sets of RFDACs 225-0 to 225-4 and 255-0 to 255-4 collectively generate a continuous RF current IOUT with a current value of (0*0.5+1*0+1*2+0*4+1*8)+(0*0.5+1*0+1*2+0*4+1*8)=10+10=20 mA.

FIG. 2C illustrates a frequency spectrum diagram of an example normalized power of the output RF signal RFOUT of the transmitter 200 in accordance with another aspect of the disclosure. The vertical axis of the frequency spectrum diagram represents the normalized power in decibel relative (dBr) associated with the output RF signal RFOUT collectively generated by the sets of RFDACs 225-0 to 225-4 and 255-0 to 255-4.

As depicted, the frequency spectrum diagram of the normalized power of the output RF signal RFOUT of the transmitter 200 includes a fundamental frequency peaking at zero (0) dBr at zero (0) Hz, and falls therefrom to about −70 dBR at around DAC image frequencies −ƒos and +ƒos, respectively. This is because the delayed digital serial signal D0-D4 in combination with the non-delayed digital serial signal effectively doubles the oversampling rate of the digital serial signal D0-D4. As previously discussed, the frequency spacing between the DAC images is the same as the effective oversampling rate of now being double the oversampling clock signal CLK or 16 GHz. As the DAC images are now pushed out to +/−8 GHz, the output capacitor C and the balun 230 may be able to provide the sufficient DAC image rejection in order to meet spectrum mask requirements.

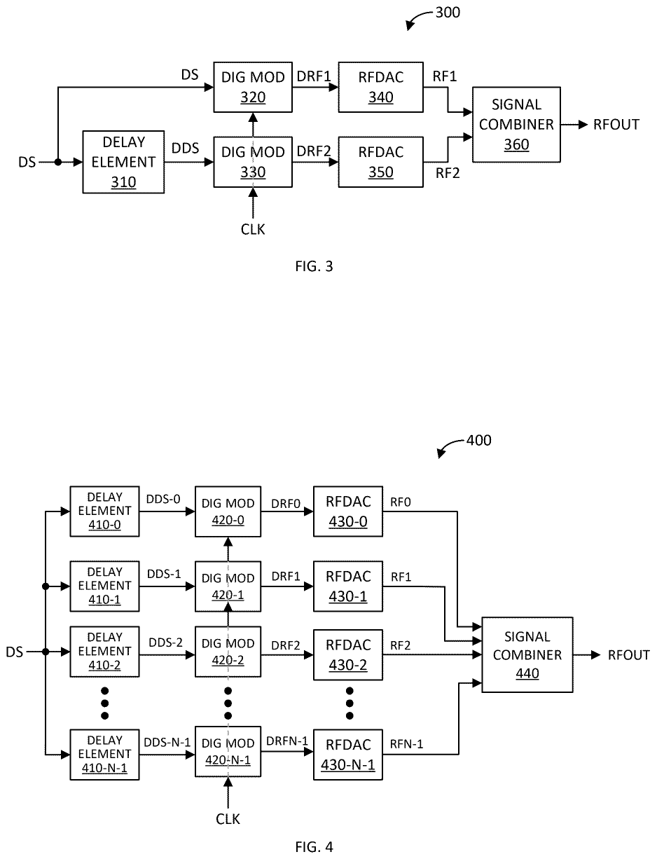

FIG. 3 illustrates a block diagram of another example transmitter 300 in accordance with another aspect of the disclosure. The transmitter 300 includes a delay element 310, a pair of digital modulators 320 and 330, a pair of radio frequency digital to analog converters (RFDACs) 340 and 350, and a signal combiner 360. The delay element 310 is configured to delay the digital signal DS to generate a delayed digital signal DDS. The digital modulator 320 is configured to modulate a clock signal CLK with the digital signal DS to generate a first digital radio frequency (RF) signal DRF1. Similarly, the digital modulator 330 is configured to modulate the clock signal CLK with the delayed digital signal DS to generate a second digital RF signal DRF2.

Additionally, the transmitter 300 includes a first radio frequency digital-to-analog converter (RFDAC) 340 configured to convert the first digital RF signal DRF1 into a first analog radio frequency (RF) signal RF1. Similarly, the transmitter 300 includes a second RFDAC 350 configured to convert the second digital RF signal DRF2 to generate a second analog RF signal RF2. The transmitter 300 also includes a signal combiner 360 configured to combine the first analog RF signal RF1 with the second analog RF signal RF2 to generate an output RF signal RFOUT. An antenna (not shown) may be coupled to the output of the signal combiner 360 for wirelessly transmitting the output RF signal RFOUT for transmission to one or more remote devices/equipment.

FIG. 4 illustrates a block diagram of another example transmitter 400 in accordance with another aspect of the disclosure. The transmitter 400 may be a more general extension of the transmitter 300 including a set of N parallel RFDACs with associated circuitry to further separate the DAC images by N/2*ƒ from the fundamental frequency or carrier of an output transmit RF signal RFOUT, wherein ƒ is the frequency of a clock signal CLK.

The transmitter 400 includes a set of N delay elements 410-0 to 410-N−1, a set of digital modulators 420-0 to 420-N−1, a set of N RFDACs 430-0 to 430-N−1, and a signal combiner 440. The set of N delay elements 410-0 to 410-N−1 include inputs coupled together and configured to receive a digital signal (DS). The set of N delay elements 410-0 to 410-N−1 are configured to delay the digital signal (DS) by substantially i/(ƒ*N) (where N is an integer, “i” is an index from zero (0) to N−1, and ƒ is a frequency of the clock signal CLK) to generate a set of delayed digital signals DDS-0 to DDS-N−1, respectively. As “i” may be zero (0), the delay element 410-0 may be optional (e.g., non-existent as in transmitters 200 and 300), but may be employed for delay calibration and/or other purposes.

The set of digital modulators 420-0 to 420-N−1 are configured to modulate the clock signal CLK with the set delayed digital signals DDS-0 to DDS-N−1 to generate a set of digital RF signals DRF0 to DRFN−1, respectively. The set of N RFDACs 430-0 to 430-N−1 are configured to convert the set of N delayed digital signals DDS-0 to DDS-N−1 into a set of N analog RF signals RF0 to RFN−1, respectively. The signal combiner 440 is configured to combine the set of N analog RF signals RF0 to RFN−1 to generate the output transmit RF signal RFOUT. An antenna (not shown) may be coupled to the output of the signal combiner 440 for wirelessly transmitting the output RF signal RFOUT to one or more remote devices/equipment, such as a WWAN base station, WLAN access point, Bluetooth receiver, keyless access receiver, etc.

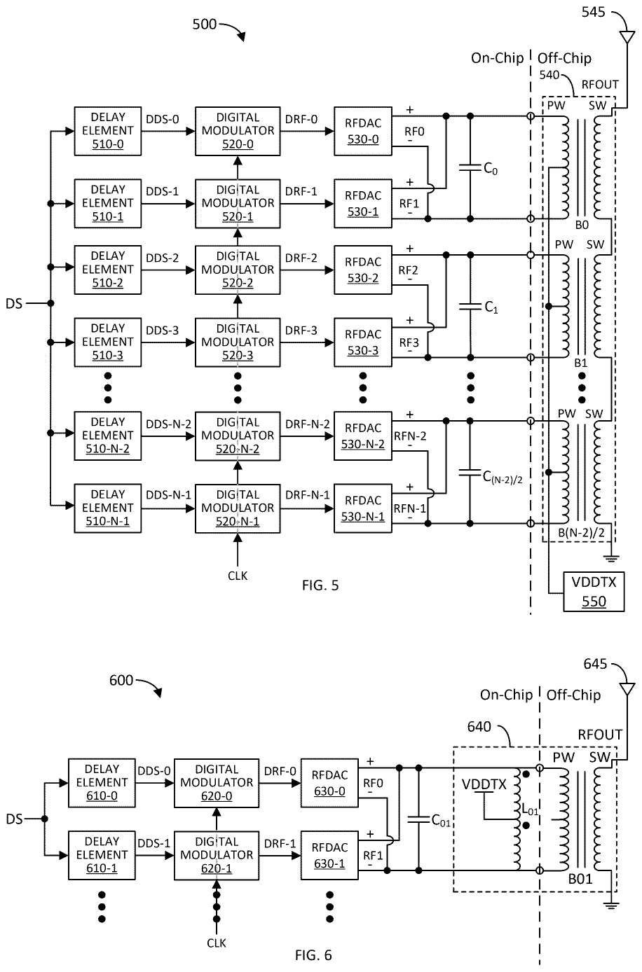

FIG. 5 illustrates a block diagram of another example transmitter 500 in accordance with another aspect of the disclosure. The transmitter 500 may be a more detailed implementation of the transmitter 400 previously discussed. The transmitter 500 includes a set of N delay elements 510-0 to 510-N−1, a set of digital modulators 520-0 to 520-N−1, a set of RFDACs 530-0 to 530-N−1, a set of N/2 output capacitors C₀ to C_{(N-2)/2}, a signal combiner 540 including a set of N/2 baluns B0 to B(N−2)/2, an antenna 545, and a transmitter supply voltage generator 550.

The set of N delay elements 510-0 to 510-N−1 are configured to delay the digital signal (DS) by substantially i/(ƒ*N) (where N is an integer, “i” is an index from zero (0) to N−1, and ƒ is a frequency of a clock signal CLK) to generate a set of delayed digital signals DDS-0 to DDS-N−1, respectively. As “i” could be zero (0), the delay element 510-0 may be optional (e.g., non-existent as in transmitters 200 and 300), but may be employed to compensate for delay calibration and/or other purposes. The set of digital modulators 520-0 to 520-N−1 are configured to modulate the clock signal CLK with the set of delayed digital signals DDS-0 to DDS-N−1 to generate a set of digital RF signals DRF0 to DRFN−1, respectively.

The set of N RFDACs 530-0 to 530-N−1 are configured to convert the set of N delayed digital signals DDS-0 to DDS-N into a set of N analog RF signals RF0 to RFN−1, respectively. In this example, the set of N analog RFDACs 520-0 to 520-N−1 include differential outputs +/− at which the set of N analog differential RF signals RF0 to RFN−1 are respectively generated. The signal combiner 540 is configured to combine the set of N analog differential RF signals RF0 to RFN−1 to generate an output transmit RF signal RFOUT. The differential outputs +/− of pairs of the set of N RFDACs 520-0/520-1, 520-2/520-3 to 520-N-2/520-N−1 are coupled across (e.g., to both ends of) primary windings (PWs) of the set of N/2 baluns B0 to B(N−2/2), respectively. The set of output capacitors C0 to C(N−2/2) are also coupled across (e.g., to both ends of) the primary windings (PWs) of the set of N/2 baluns B0 to B(N−2/2), respectively. A supply voltage VDDTX, generated by the transmitter supply voltage generator 550, may be provided to the set of RFDACs 530-0/530-1, 530-1/530-2 to 530-N−2/530-N−1 via center taps of the primary windings (PWs) of the set of baluns B0, B1 to B(N−2)/2, respectively. The secondary windings (SWs) of the set of N/2 baluns B0 to B(N−2/2) are coupled between the antenna 545 (or antenna port) and a lower voltage rail (e.g., ground). In such configuration, the output transmit RF signal RFOUT is provided to the antenna 545 for wireless transmission. The balun 540, the transmitter supply voltage generator (VDDTX) 550, and antenna 545 may be off-chip as indicated by the vertical large-dashed line, and the remaining components of the transmitter 500 may be on-chip.

FIG. 6 illustrates a block diagram of another example transmitter 600 in accordance with another aspect of the disclosure. The transmitter 600 includes a set of delay elements 610-0 and 610-1, a set of digital modulators 620-0 and 620-1, a set of RFDACs 630-0 and 630-1, an output capacitor C₀₁, a signal combiner 640, and an antenna 645. The signal combiner 640 includes a differential inductor L₀₁ and a balun B01.

The delay elements 610-0 and 610-1 are configured to substantially delay the digital signal (DS) by substantially zero (0) and 1/(2*ƒ) (where ƒ is a frequency of a clock signal CLK) to generate delayed digital signals DDS-0 and DDS-1, respectively. As previously indicated, the delay element 610-0 may be optional (e.g., non-existent as in transmitters 200 and 300), but may be employed for delay calibration and/or other purposes. As indicated by the ellipsis, it shall be understood that the transmitter 600 may include additional parallel delay elements, digital modulators, and RF DACs as per transmitters 400 and 500. The set of digital modulators 620-0 and 620-1 are configured to modulate the clock signal CLK with delayed digital signals DDS-0 and DDS-1 to generate digital RF signals DRF0 and DRFN−1, respectively.

The RFDACs 620-0 and 620-1 are configured to convert the delayed digital signals DDS-0 and DDS-1 into analog differential RF signals RF0 and RF1 at differential outputs +/− thereof, respectively. The differential outputs +/− of RFDACs 620-0 and 620-1 are coupled across (e.g., to both ends of) the output capacitor C₀₁, the differential inductor L₀₁, and the primary winding (PW) of the balun B01. A supply voltage VDDTX, internally routed on-chip, may be provided to the RFDACs 620-0 to 620-1 via a center tap of the differential inductor L₀₁. An output transmit RF signal RFOUT, being related to a sum of the analog differential RF signals RF0 and RF1, is generated across the secondary winding (SW) of the balun B01, where the secondary winding (SW) is coupled between the antenna 645 and a lower voltage rail (e.g., ground). The antenna 645 is configured to electromagnetically radiate the output transmit signal RFOUT for transmission to one or more remote devices/equipment. The balun B01 and antenna 645 may be off-chip as indicated by the vertical large-dashed line, and the remaining components of the transmitter 600 may be on-chip.

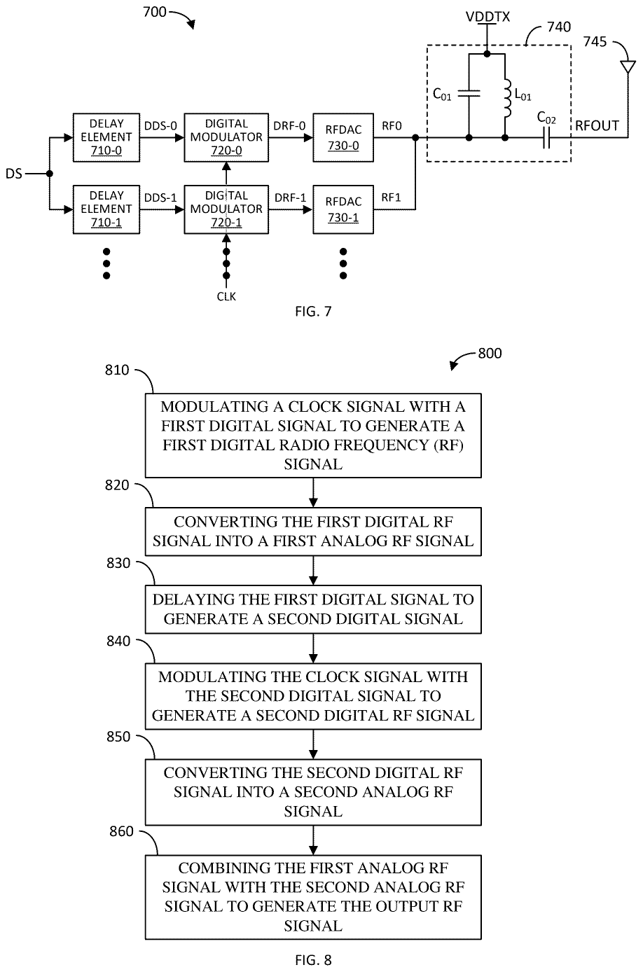

FIG. 7 illustrates a block diagram of another example transmitter 700 in accordance with another aspect of the disclosure. The transmitter 700 includes a set of delay elements 710-0 and 710-1, a set of digital modulators 720-0 and 720-1, a set of RFDACs 730-0 and 730-1, a signal combiner 740, and an antenna 745. The signal combiner 740 includes a shunt capacitor C01 coupled in parallel with a shunt inductor L₀₁ between the outputs of the RFDACs 730-0 and 730-1 and an upper voltage rail VDDTX (e.g., virtual ground), and an alternating current (AC) coupling capacitor C₀₂. A supply voltage VDDTX is provided to the RFDACs 730-0 and 730-1 via the shunt inductor L₀₁. The signal combiner 740, which is suitable for combining single-ended signals, may be simpler, require less parts, cost less, and occupy less circuit area compared to the balun-based signal combiners 230, 540, and 640.

The delay elements 710-0 and 710-1 are configured to substantially delay a digital signal (DS) by substantially zero (0) and 1/(2*ƒ) to generate delayed digital signals DDS-0 and DDS-1, respectively. As previously indicated, the delay element 710-0 may be optional (e.g., non-existent as in transmitters 200 and 300), but may be employed delay calibration and/or other purposes. As indicated by the ellipsis, it shall be understood that transmitter 700 may include additional parallel delay elements, digital modulators, and RF DACs as per transmitters 400 and 500. The digital modulators 720-0 and 720-1 are configured to modulate the clock signal CLK with delayed digital signals DDS-0 and DDS-1 to generate digital RF signals DRF0 and DRFN−1, respectively.

The RFDACs 720-0 and 720-1 are configured to convert the delayed digital signals DDS-0 and DDS-1 into single-ended analog RF signals RF0 and RF1, respectively. The RFDACs 720-0 and 720-1 include outputs coupled to an input of the signal combiner 730. The signal combiner 730 is configured to combine the single-ended analog RF signals RF0 and RF1 into an output transmit signal RFOUT. The antenna 635 is configured to receive and electromagnetically radiate the output transmit signal RFOUT for transmission to one or more remote devices/equipment.

FIG. 8 illustrates a flow diagram of an example method 800 of generating an output RF signal in accordance with another aspect of the disclosure. The method 800 includes modulating a clock signal with a first digital signal to generate a first digital radio frequency (RF) signal (block 810). Examples of means for modulating a clock signal with a first digital signal to generate a first digital radio frequency (RF) signal include any of the digital modulators described herein. The method 800 further includes converting the first digital RF signal into a first analog RF signal (block 820). Examples of means for converting the first digital RF signal into a first analog RF signal include any of the RFDACs described herein. The method 800 further includes delaying the first digital signal to generate a second digital signal (block 830). Examples of means for delaying the first digital signal to generate a second digital signal include any of the delay elements described herein.

The method 800 also includes modulating the clock signal with the second digital signal to generate a second digital RF signal (block 840). Examples of means for modulating the clock signal with the second digital signal to generate a second digital RF signal include any of the digital modulators described herein. Further, the method 800 includes converting the second digital RF signal into a second analog RF signal (block 850). Examples of means for converting the second digital RF signal into a second analog RF signal include any of the RFDACs described herein. Additionally, the method 800 includes combining the first analog RF signal with the second analog RF signal to generate the output RF signal (block 860). Examples of means for combining the first analog RF signal with the second analog RF signal to generate the output RF signal include the signal combiners described herein.

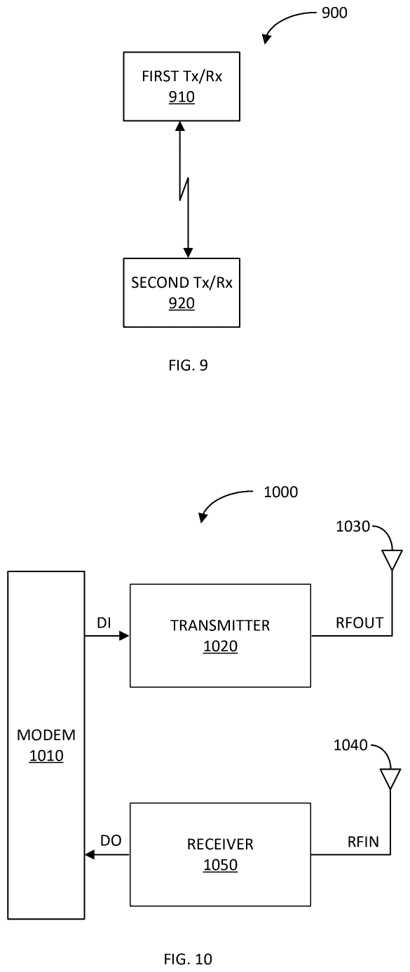

FIG. 9 illustrates a block diagram of an example wireless communication system 900 in accordance with another aspect of the disclosure. The wireless communication system 900 includes a first transceiver (Tx/Rx) 910 wirelessly coupled to a second transceiver (Tx/Rx) 920. As some examples, the first transceiver 910 may be implemented as a wireless wideband area network (WWAN) base station (BS), a wireless local area network (WLAN) access point (AP), a Bluetooth transceiver, a keyless access ultra wideband (UWB) transceiver, and/or other type of transceiver. The second transceiver 920 may be implemented as a user equipment (UE) configured to wirelessly communicate with the first transceiver 910 via one or more wireless communication protocols, such as New Radio (NR) 5^{th} or 6^{th} Generation (5G) or (6G), WiFi, Bluetooth, UWB, and/or other type of protocol. The first transceiver 910 and/or second transceiver 920 may each implement any one of the transmitters 200, 300, 400, 500, 600, or 700 described herein.

FIG. 10 illustrates a block diagram of an example transceiver 1000 in accordance with another aspect of the disclosure. The transceiver 1000 may be an example implementation of the first and/or second transceivers 910 and 920 of wireless communication system 900.

The transceiver 1000 includes a modem 1010, a transmitter 1020, a transmit antenna 1030, a receive antenna 1040, and a receiver 1050. The modem 1010 is configured to generate a parallel transmit baseband signal DI. The transmitter 1020 is configured to generate an output RF signal RFOUT based on the input parallel baseband digital signal DI. The transmitter 1020 may be implemented per any one of the transmitter 200, 300, 400, 500, 600, or 700. The transmit antenna 1030 is configured to wirelessly transmit the output RF signal RFOUT.

The receive antenna 1040 is configured to receive an input RF signal RFIN. Although the transceiver 1000 is shown to have both transmit and receive antennas 1030 and 1040, it shall be understood that the transmitter may have a single antenna common to both the transmitter 1020 and the receiver 1050. The receiver 1050 is configured to convert the input RF signal RFIN into a parallel baseband digital signal DO. The modem 1010 is configured to receive and process the parallel baseband digital signal DO to extract/recover data/information therefrom.

The following provides an overview of aspects of the present disclosure:

Aspect 1: A transmitter, comprising: a first delay element configured to delay a first digital signal to generate a second digital signal; a first digital modulator configured to modulate a clock signal with the first digital signal to generate a first digital radio frequency (RF) signal; a second digital modulator configured to modulate the clock signal with the second digital signal to generate a second digital RF signal; a first radio frequency digital to analog converter (RFDAC) configured to convert the first digital signal into a first analog RF signal; a second RFDAC configured to convert the second digital RF signal to generate a second analog RF signal; and a signal combiner configured to combine the first analog RF signal with the second analog RF signal to generate an output RF signal.

Aspect 2: The transmitter of aspect 1, wherein: the first digital modulator including a first logic gate including first input configured to receive the clock signal, a second input configured to receive the first digital signal, and an output coupled to an input of the first RFDAC; and the second digital modulator includes a second logic gate including a first input configured to receive the clock signal, a second input coupled to the first delay element to receive the second digital signal, and an output coupled to an input of the second RFDAC.

Aspect 3: The transmitter of aspect 2, wherein the first logic gate and the second logic gate are each an AND gate.

Aspect 4: The transmitter of any one of aspects 1-3, wherein a delay effectuated by the first delay element upon the first digital signal is related to a frequency of the clock signal.

Aspect 5: The transmitter of any one of aspects 1-4, wherein the signal combiner comprises a balun.

Aspect 6: The transmitter of aspect 5, wherein: the balun includes a primary winding (PW); the first RFDAC includes positive and negative outputs coupled to both ends of the primary winding (PW) of the balun, respectively; and the second RFDAC includes positive and negative outputs coupled to both ends of the primary winding (PW) of the balun, respectively.

Aspect 7: The transmitter of aspect 6, wherein the balun comprises a secondary winding (SW) coupled between an antenna and ground.

Aspect 8: The transmitter of any one of aspects 1-4, wherein the signal combiner comprises: an inductor; and a balun including a primary winding (PW) and a secondary winding (SW), the first and second RFDACs each includes positive and negative outputs coupled to both ends of the inductor and the primary winding (PW) of the balun, wherein the secondary winding (SW) coupled between an antenna and ground.

Aspect 9: The transmitter of any one of aspects 1-4, wherein the signal combiner comprises a capacitor and an inductor coupled in parallel between outputs of the first and second RFDACs and a virtual ground.

Aspect 10: The transmitter of any one of aspects 1-4, further comprising: a second delay element configured to delay the first digital signal to generate a third digital signal; a third delay element configured to delay the first digital signal to generate a fourth digital signal; a third digital modulator configured to modulate the clock signal with the third digital signal to generate a third digital RF signal; a fourth digital modulator configured to modulate the clock signal with the fourth digital signal to generate a fourth digital RF signal; a third RFDAC configured to convert the third digital RF signal into a third analog RF signal; and a fourth RF DAC configured to convert the fourth digital RF signal into a fourth analog RF signal.

Aspect 11: The transmitter of aspect 10, wherein the signal combiner comprises: a first balun including a first primary winding (PW) and a first secondary winding (SW), wherein the first and second RFDACs include respective differential outputs coupled to both ends of the first primary winding (PW), respectively; and a second balun including a second primary winding (PW) and a second secondary winding (SW), wherein the third and fourth RFDACs include respective differential outputs coupled to both ends of the second primary winding (PW); wherein the first and second secondary windings are coupled in series between an antenna port and ground.

Aspect 12: A method of generating an output RF signal, comprising: modulating a clock signal with a first digital signal to generate a first digital radio frequency (RF) signal; converting the first digital signal into a first analog RF signal; modulating the clock signal with the second digital signal to generate a second digital RF signal; converting the second digital RF signal into a second analog RF signal; and combining the first analog RF signal with the second analog RF signal to generate the output RF signal.

Aspect 13: The method of aspect 12, wherein delaying the first digital signal comprises delaying the first digital signal by an amount related to frequency of the clock signal.

Aspect 14: The method of aspect 12 or 13, wherein combining the first analog RF signal with the second analog RF signal to generate the output RF signal comprises applying the first and second analog RF signals across a primary winding (PW) of a balun, wherein the output RF signal is generated across a secondary winding (SW) of the balun.

Aspect 15: The method of aspect 14, further comprising providing the output RF signal to an antenna for wireless transmission.

Aspect 16: The method of aspect 12 or 13, wherein combining the first analog RF signal with the second analog RF signal to generate the output RF signal comprises applying the first and second analog RF signals across an inductor coupled in parallel with a primary winding (PW) of a balun, wherein the output RF signal is generated across a secondary winding (SW) of the balun.

Aspect 17: The method of aspect 12 or 13, wherein combining the first analog RF signal with the second analog RF signal to generate the output RF signal comprises applying the first and second analog RF signals a shunt inductor coupled in parallel with a shunt capacitor.

Aspect 18: The method of aspect 12 or 13, further comprising: delaying the first digital signal to generate a third digital signal; delay the first digital signal to generate a fourth digital signal; modulating the clock signal with the third digital signal to generate a third digital RF signal; modulating the clock signal with the fourth digital signal to generate a fourth digital RF signal; converting the third digital RF signal into a third analog RF signal; and converting the fourth digital RF signal into a fourth analog RF signal.

Aspect 19: The method of aspect 18, wherein combining the first analog RF signal with the second analog RF signal to generate the output RF signal comprises: applying the first and second analog RF signals across a first primary winding (PW) of a first balun; applying the third and fourth analog RF signals across a second primary winding (PW) of a second balun; and generating the output RF signal across first and second secondary windings (SWs) of the first and second baluns, respectively.

Aspect 20: A transmitter, comprising: means for modulating a clock signal with a first digital signal to generate a first digital radio frequency (RF) signal; means for converting the first digital signal into a first analog RF signal; means for delaying the first digital signal to generate a second digital RF signal; means for converting the second digital RF signal into a second analog RF signal; and means for combining the first analog RF signal with the second analog RF signal to generate an output RF signal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. A transmitter, comprising:
a first delay element configured to delay a first digital signal to generate a second digital signal;
a first digital modulator configured to modulate a clock signal with the first digital signal to generate a first digital radio frequency (RF) signal;
a second digital modulator configured to modulate the clock signal with the second digital signal to generate a second digital RF signal;
a first radio frequency digital-to-analog converter (RFDAC) configured to convert the first digital RF signal to generate a first analog RF signal;
a second RFDAC configured to convert the second digital RF signal to generate a second analog RF signal; and
a signal combiner configured to combine the first analog RF signal with the second analog RF signal to generate an output RF signal.

2. The transmitter of claim 1, wherein:
the first digital modulator includes a first logic gate including a first input configured to receive the clock signal, a second input configured to receive the first digital signal, and an output coupled to an input of the first RFDAC; and
the second digital modulator includes a second logic gate including a first input configured to receive the clock signal, a second input coupled to the first delay element to receive the second digital signal, and an output coupled to an input of the second RFDAC.

3. The transmitter of claim 2, wherein the first logic gate and the second logic gate are each an AND gate.

4. The transmitter of claim 1, wherein a delay effectuated by the first delay element upon the first digital signal is related to a frequency of the clock signal.

5. The transmitter of claim 1, wherein the signal combiner comprises a balun.

6. The transmitter of claim 5, wherein:
the balun includes a primary winding (PW);
the first RFDAC includes positive and negative outputs coupled to both ends of the primary winding (PW) of the balun, respectively; and
the second RFDAC includes positive and negative outputs coupled to both ends of the primary winding (PW) of the balun, respectively.

7. The transmitter of claim 6, wherein the balun comprises a secondary winding (SW) coupled between an antenna and ground.

8. The transmitter of claim 1, wherein the signal combiner comprises:
an inductor; and
a balun including a primary winding (PW) and a secondary winding (SW), the first and second RFDACs each includes positive and negative outputs coupled to both ends of the inductor and the primary winding (PW) of the balun, wherein the secondary winding (SW) coupled between an antenna and ground.

9. The transmitter of claim 1, wherein the signal combiner comprises a capacitor and an inductor coupled in parallel between outputs of the first and second RFDACs and a virtual ground.

10. The transmitter of claim 1, further comprising:
a second delay element configured to delay the first digital signal to generate a third digital signal;
a third delay element configured to delay the first digital signal to generate a fourth digital signal;
a third digital modulator configured to modulate the clock signal with the third digital signal to generate a third digital RF signal;
a fourth digital modulator configured to modulate the clock signal with the fourth digital signal to generate a fourth digital RF signal;
a third RFDAC configured to convert the third digital RF signal into a third analog RF signal; and
a fourth RF DAC configured to convert the fourth digital RF signal into a fourth analog RF signal.

11. The transmitter of claim 10, wherein the signal combiner comprises:
a first balun including a first primary winding (PW) and a first secondary winding (SW), wherein the first and second RFDACs include respective differential outputs coupled to both ends of the first primary winding (PW), respectively; and
a second balun including a second primary winding (PW) and a second secondary winding (SW), wherein the third and fourth RFDACs include respective differential outputs coupled to both ends of the second primary winding (PW);
wherein the first and second secondary windings are coupled in series between an antenna port and ground.

12. A method of generating an output RF signal, comprising:
modulating a clock signal with a first digital signal to generate a first digital radio frequency (RF) signal;
converting the first digital RF signal into a first analog RF signal;
delaying the first digital signal to generate a second digital signal;
modulating the clock signal with the second digital signal to generate a second digital RF signal;
converting the second digital RF signal into a second analog RF signal; and
combining the first analog RF signal with the second analog RF signal to generate the output RF signal.

13. The method of claim 12, wherein delaying the first digital signal comprises delaying the first digital signal by an amount related to a frequency of the clock signal.

14. The method of claim 12, wherein combining the first analog RF signal with the second analog RF signal to generate the output RF signal comprises applying the first and second analog RF signals across a primary winding (PW) of a balun, wherein the output RF signal is generated across a secondary winding (SW) of the balun.

15. The method of claim 14, further comprising providing the output RF signal to an antenna for wireless transmission.

16. The method of claim 12, wherein combining the first analog RF signal with the second analog RF signal to generate the output RF signal comprises applying the first and second analog RF signals across an inductor coupled in parallel with a primary winding (PW) of a balun, wherein the output RF signal is generated across a secondary winding (SW) of the balun.

17. The method of claim 12, wherein combining the first analog RF signal with the second analog RF signal to generate the output RF signal comprises applying the first and second analog RF signals a shunt inductor coupled in parallel with a shunt capacitor.

18. The method of claim 12, further comprising:
delaying the first digital signal to generate a third digital signal;
delay the first digital signal to generate a fourth digital signal;
modulating the clock signal with the third digital signal to generate a third digital RF signal;
modulating the clock signal with the fourth digital signal to generate a fourth digital RF signal;
converting the third digital RF signal into a third analog RF signal; and
converting the fourth digital RF signal into a fourth analog RF signal.

19. The method of claim 18, wherein combining the first analog RF signal with the second analog RF signal to generate the output RF signal comprises:
applying the first and second analog RF signals across a first primary winding (PW) of a first balun;
applying the third and fourth analog RF signals across a second primary winding (PW) of a second balun; and
generating the output RF signal across first and second secondary windings (SWs) of the first and second baluns, respectively.

20. A transmitter, comprising:
means for modulating a clock signal with a first digital signal to generate a first digital radio frequency (RF) signal;
means for converting the first digital signal into a first analog RF signal;
means for delaying the first digital signal to generate a second digital signal;
means for modulating the clock signal with the second digital signal to generate a second digital RF signal;
means for converting the second digital RF signal into a second analog RF signal; and
means for combining the first analog RF signal with the second analog RF signal to generate an output RF signal.
